(19) United States
(12) Patent Application Publication
(10) Pub. No.: US 2025/0165665 A1
(43) Pub. Date: May 22, 2025

(54) APPARATUS AND METHOD FOR VERIFYING PERFORMANCE OF BATTERY MANAGEMENT SYSTEM

(71) Applicant: SAMSUNG SDI CO., LTD., Yongin-si (KR)

(72) Inventor: Minsu KIM, Yongin-si (KR)

(21) Appl. No.: 18/644,420

(22) Filed: Apr. 24, 2024

(30) Foreign Application Priority Data
Nov. 16, 2023 (KR) 10-2023-0159286

(51) Int. Cl. G06F 30/20; H01M 10/42

(52) U.S. Cl. CPC G06F 30/20; H01M 10/425; H01M 2010/4271

(57) ABSTRACT

An apparatus and method for verifying performance of a battery management system (BMS). The apparatus includes a data collecting module configured to collect element-specific measurement data of the BMS, a virtualizing module configured to generate, based on the element-specific measurement data, a BMS virtual model, an emulating module configured to perform emulation for each of multiple scenarios using the BMS virtual model and a data analyzing module configured to analyze emulation result data and output whether the BMS is defective, and output a countermeasure.

### CROSS-REFERENCE TO RELATED APPLICATION

The present application claims priority and the benefit of Korean Patent Application No. 10-2023-0159286, filed on Nov. 16, 2023, in the Korean Intellectual Property Office, the entire disclosure of which is incorporated herein by reference in its entirety.

### BACKGROUND

### 1. Field

One or more embodiments relate to an apparatus and method for verifying performance of a battery management system, and more particularly, to an apparatus and method for verifying performance of a battery management system in which a failure may be detected through emulation in a process of manufacturing the battery management system.

### 2. Description of the Related Art

A secondary battery refers to a chargeable and dischargeable battery, unlike a primary battery that is not chargeable. Low-capacity secondary batteries are used in small portable electronic devices such as smartphones, feature phones, laptop computers, digital cameras, and camcorders, and high-capacity secondary batteries are used as motor-driving power sources, power-storing batteries, etc., for hybrid vehicles, electric vehicles, etc. Such a secondary battery may include an electrode assembly including a cathode and an anode, a case accommodating the electrode assembly, an electrode terminal connected to the electrode assembly, etc.

A battery management system (BMS) monitors and manages a state of a secondary battery used for hybrid vehicles, electric vehicles, etc., and optimizes the stability, performance, lifespan, etc., of the secondary battery.

Malfunctions or defects in a BMS may cause dangerous situations such as over-charging, over-discharging, and over-heating of the secondary battery. Accordingly, detecting in advance and responding to malfunctions or defects in a BMS is desirable.

The above-described information disclosed in the technology that serves as the background of the present disclosure is only for improving understanding of the background of the present disclosure.

### SUMMARY

Embodiments include an apparatus for verifying performance of a battery management system (BMS). The apparatus includes a data collecting module configured to collect element-specific measurement data of the BMS, a virtualizing module configured to generate, based on the element-specific measurement data, a BMS virtual model, an emulating module configured to perform emulation for each of a plurality of scenarios using the BMS virtual model and a data analyzing module configured to analyze emulation result data, output whether the BMS is defective and output a countermeasure.

The element-specific measurement data may include at least one of identification data, electrical response characteristic data, power characteristic data, input/output response characteristic data and sensing data.

The at least one of the electrical response characteristic data, the power characteristic data, the input/output response characteristic data and the sensing data may indicate an average value of a plurality of measurement data.

The virtualizing module may be further configured to pre-process the element-specific measurement data, profile the pre-processed element-specific measurement data and aggregate the profiled element-specific measurement data to generate the BMS virtual model.

The virtualizing module may be further configured to pre-process the element-specific measurement data by performing at least one of normalization of the element-specific measurement data and generation of feature data based on the element-specific measurement data.

The virtualizing module may be further configured to profile the pre-processed element-specific measurement data by performing at least one of generation of an element-specific unique profile based on the pre-processed element-specific measurement data and grouping of elements having similar unique profiles.

Each of the unique profiles generated may include data of an element regarding electrical characteristics, response time and input/output processing capabilities.

The emulating module may be further configured to initialize an emulation environment, select a scenario of the plurality of scenarios and perform emulation of the selected scenario using the BMS virtual model.

The data analyzing module may be further configured to pre-process the emulation result data, perform machine learning based on the pre-processed emulation result data, determine, based on a result of performing the machine learning, whether the BMS is defective and generate a countermeasure according to whether the BMS is defective.

The data analyzing module may be further configured to, if it is determined that there is a defect in the BMS, identify a cause for the defect and generate an appropriate countermeasure against the defect.

Embodiments include a method of verifying performance of a battery management system (BMS). The method includes collecting, by a data collecting module, element-specific measurement data of the BMS, generating, by a virtualizing module, a BMS virtual model, based on the element-specific measurement data, performing, by an emulating module, emulation for each of a plurality of scenarios using the BMS virtual module and analyzing, by a data analyzing module, emulation result data, outputting whether the BMS is defective and outputting a countermeasure.

The element-specific measurement data may include at least one of identification data, electrical response characteristic data, power characteristic data, input/output response characteristic data and sensing data.

The at least one of the electrical response characteristic data, the power characteristic data, the input/output response characteristic data and the sensing data may indicate an average value of a plurality of measurement data.

Generating of the BMS virtual model may include pre-processing the element-specific measurement data, profiling the pre-processed element-specific measurement data and aggregating the profiled element-specific measurement data to generate the BMS virtual model.

Pre-processing of the element-specific measurement data may include pre-processing the element-specific measurement data by performing at least one of: normalization of the element-specific measurement data and generation of feature data based on the element-specific measurement data.

Profiling of the pre-processed element-specific measurement data may include profiling the pre-processed element-specific measurement data by performing at least one of: generation of an element-specific unique profile based on the pre-processed element-specific measurement data and grouping of elements having similar unique profiles.

The unique profiles may include data of an element regarding electrical characteristics, response time and input/output processing capabilities.

Performing of emulation for each of the plurality of scenarios may include initializing an emulation environment, selecting a scenario of the plurality of scenarios and performing emulation of the selected scenario using the BMS virtual model.

Outputting of whether the BMS is defective and outputting of the countermeasure may include pre-processing, by the data analyzing module, the emulation result data, performing machine learning based on the pre-processed emulation result data, determining, based on a result of performing the machine learning, whether the BMS is defective and generating a countermeasure according to whether the BMS is defective.

The method may further include identifying, by the data analyzing module, if it is determined that there is a defect in the BMS, a cause for the defect and generating, by the data analyzing module, an appropriate countermeasure against the defect.

### BRIEF DESCRIPTION OF THE DRAWINGS

Features will become apparent to those of ordinary skill in the art by describing in detail exemplary embodiments with reference to the attached drawings in which:

FIG. 1 is a block diagram of an apparatus for verifying performance of a battery management system (BMS) according to one or more embodiments of the present disclosure;

FIG. 2 is a flowchart of a performance verification method of a BMS according to one or more embodiments of the present disclosure;

FIG. 3 is a flowchart of a method of generating a BMS virtual model of a BMS according to one or more embodiments of the present disclosure; and

FIG. 4 is a flowchart of a method of performing emulation using a BMS virtual model of a BMS according to one or more embodiments of the present disclosure.

### DETAILED DESCRIPTION

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, the term “and/or” includes any and all combinations of one or more of the associated listed items. Expressions such as “at least one of,” if preceding a list of elements, modify the entire list of elements and do not modify the individual elements of the list.

The terms and words used in the present specification and claims described above should not be construed as being limited to ordinary or dictionary meanings, and should be interpreted as meanings and concepts consistent with the technical idea of the present disclosure based on the principle that the present inventors may appropriately define the concept of the terms to describe the various embodiments in the best way. Therefore, it should be understood that the configurations shown in the drawings and embodiments described in this specification are merely the most preferred embodiments of the present disclosure, and do not represent all of the technical ideas of the present disclosure, such that there may be various equivalents and variations that replace them at the time of filing the present application. If used herein, “comprise, include” and/or “comprising, including” specify mentioned shapes, numbers, steps, operations, members, components, and/or presence of these groups, and do not exclude the presence or addition of one or more different shapes, numbers, operations, members, components, and/or groups. When embodiments of the present disclosure are described, “can” or “may” may include “one or more embodiments of the present disclosure”.

Throughout the specification, unless specially stated to the contrary, each component may be singular or plural.

If a component is described as being “connected”, “coupled”, or “connected” to another component, it should be understood that the components are directly connected or connectable to each other, but another component may be “interposed” between the components, or the components may be may be “connected”, “coupled”, or “connected” to each other through another component. If a portion is electrically coupled to another portion, this may include not only a case where they are directly connected to each other, but also a case where they are connected with another element therebetween.

Throughout the specification, “A and/or B” may mean A, B, or A and B unless specially stated otherwise. That is, “and/or” may include all or any combination of a plurality of items listed. “C to D” may mean at least C but not more than D, unless specially stated otherwise.

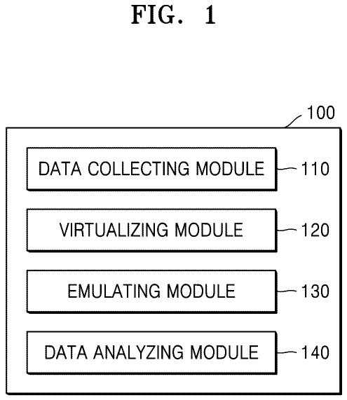

FIG. 1 is a block diagram of an apparatus for verifying performance of a battery management system (BMS) according to one or more embodiments of the present disclosure.

Referring to FIG. 1, an apparatus 100 for verifying performance of a BMS according to embodiments of the present disclosure may include a data collecting module 110, a virtualizing module 120, an emulating module 130 and a data analyzing module 140.

The data collecting module 110 may collect measurement data for each element, i.e., element-specific measurement data, of the BMS.

The BMS may be included, together with a battery, in a battery pack and may manage the battery. The BMS may include a detection device, a balancing device and a control device.

The detection device may sense a state of the battery to detect state information indicating the state of the battery. The state of the battery may include, for example, a voltage, a current, a temperature, etc., of the battery.

The balancing device may perform a balancing operation of the battery.

The control device may monitor and calculate the state of the battery based on the state information of the battery received from the detection device. The state of the battery may include, for example, a voltage, a current, a temperature, a state of charge (SOC), a state of health (SOH), etc., of the battery.

The control device may perform a control function, a protection function, etc., for the battery, based on a state monitoring result. The control function may include, for example, temperature control, balancing control, charging/discharging control, etc. The protection function may include, for example, over-discharging prevention, over-charging prevention, over-current prevention, short-circuit, an extinguishing function, etc.

The control device may perform communication with an external device of the battery pack.

An element of the BMS may mean a hardware element of a device included in the BMS. The hardware element may include, for example, an integrated circuit (IC).

The element-specific measurement data may be data measured for each hardware element of the device included in the BMS.

The element-specific measurement data may include at least one of identification data, electrical response characteristic data, power characteristic data, input/output response characteristic data and sensing data.

The identification data may be used to distinguish an element from other elements. The identification data may include, for example, a serial number, a manufacturing date, a batch number, etc., of the element.

The electrical response characteristic data may include, for example, measurement data of a voltage, a current, a resistance, a power, a power efficiency, a power factor, etc., of the element.

The input/output response characteristic data may mean the response characteristic data of an input/output signal of the element.

The input/output response characteristic data may include measurement data of a response time, a change gradient, a speed, etc., of a signal.

In some embodiments, the input/output response characteristic data may include a toggle time of general-purpose input/output (GPIO), a transmission time of a universal asynchronous receiver/transmitter (UART), a transmission time of a serial peripheral interface (SPI), a read/write time of an inter-integrated circuit (I2C), a conversion time of an analog-to-digital converter (ADC), a period time of pulse-width modulation (PWM), etc.

The sensing data may include, for example, measurement data of a temperature, a humidity, vibration, etc., of an element or around the element.

In one or more embodiments, at least one of the electrical response characteristic data, the power characteristic data, the input/output response characteristic data and the sensing data may indicate an average value of a plurality of pieces of measurement data. In some embodiments, a representative value other than the average value may also be indicated.

The virtualizing module 120 may generate a BMS virtual model based on the element-specific measurement data.

The virtualizing module 120 may receive the element-specific measurement data from the data collecting module 110, pre-process the received element-specific measurement data, profile the pre-processed element-specific measurement data and aggregate the profiled element-specific measurement data to generate the BMS virtual model.

The virtualizing module 120 may perform consistent analysis by performing pre-processing to normalize element-specific measurement data having a different unit and/or range.

The virtualizing module 120 may generate new feature data by combining the element-specific measurement data. In an example embodiment, the virtualizing module 120 may generate power data that is a new feature using voltage data and current data.

The virtualizing module 120 may profile the element-specific measurement data by generating a unique profile per element based on the pre-processed element-specific measurement data. The unique profile may include, for example, data regarding electrical characteristics, response time, an input/output processing capability, etc., of the element.

The virtualizing module 120 may identify elements performing similar functions by grouping elements having similar unique profiles.

The virtualizing module 120 may map a position and a function of the element based on the profiled element-specific measurement data and aggregate information about the element and an element group to generate one BMS virtual model.

The BMS virtual model may include data available to the emulating module 130 to perform emulation.

The virtualizing module 120 may verify whether the BMS virtual model matches an actual BMS architecture. The virtualizing module 120 may verify the match between the BMS virtual model and the actual BMS architecture, using, for example, a statistical indicator such as an R-squared value, a root mean square error (RMSE), etc. The emulating module 130 may perform emulation for each scenario using the BMS virtual model.

The emulating module 130 may initialize an emulation environment, select a scenario and perform emulation of the selected scenario using the BMS virtual module generated by the virtualizing module 120.

The emulating module 130 may initialize the emulation environment and

allocate a required resource. The emulating module 130 may load an emulation file provided by the virtualizing module 120.

The emulating module 130 may select one of a plurality of preset scenarios and perform emulation according to the selected preset scenario using the BMS virtual model.

The emulating module 130 may collect emulation result data resulting from the emulation. The emulation result data may include, for example, statistical data, graph data, etc.

The data analyzing module 140 may analyze the emulation result data to output whether the BMS is defective and output a countermeasure.

The data analyzing module 140 may pre-process the emulation result data.

The data analyzing module 140 may perform pre-processing such as, for example, normalization such as noise filtering, data aggregation, scaling, etc., with respect to the emulation result data.

The data analyzing module 140 may perform analysis, for example, statistical analysis, time-series analysis, machine learning algorithm, etc., on the emulation result data.

The statistical analysis may mean calculation of, for example, an average, a standard deviation, a variance, etc.

The time-series analysis may mean pattern analysis of data over time.

The machine learning algorithm may mean an algorithm such as classification, recursion, clustering, etc.

The data analyzing module 140 may analyze a cause for a defect of the element using, for example, a data analysis result, monitor a key performance indicator and predict predictive maintenance.

If it is determined that there is a defect in the element, the data analyzing module 140 may identify the cause for the defect and generate an appropriate countermeasure against the defect.

The data analyzing module 140 may perform, for example, automated decision-making, e.g., transmission of a notification, etc., if it is determined that there is the defect in the element.

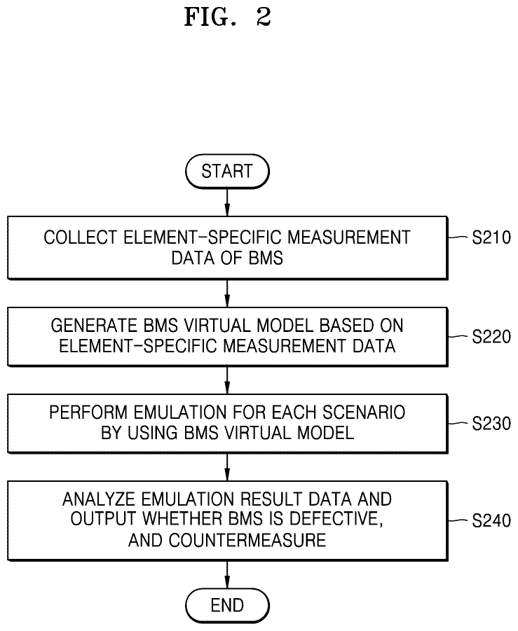

FIG. 2 is a flowchart of a performance verifying method of a BMS according to one or more embodiments of the present disclosure.

Referring to FIG. 2, the data collecting module 110 may collect element-specific measurement data of the BMS, in operation S210.

The data collecting module 110 may collect data measured for a hardware element of a device included in the BMS, e.g., an integrated circuit.

The element-specific measurement data may include at least one of identification data, electrical response characteristic data, power characteristic data, input/output response characteristic data and sensing data.

At least one of the electrical response characteristic data, the power characteristic data, the input/output response characteristic data and the sensing data may indicate a representative value such as, for example, an average value of a plurality of pieces of measurement data.

The virtualizing module 120 may generate a BMS virtual model based on the element-specific measurement data, in operation S220.

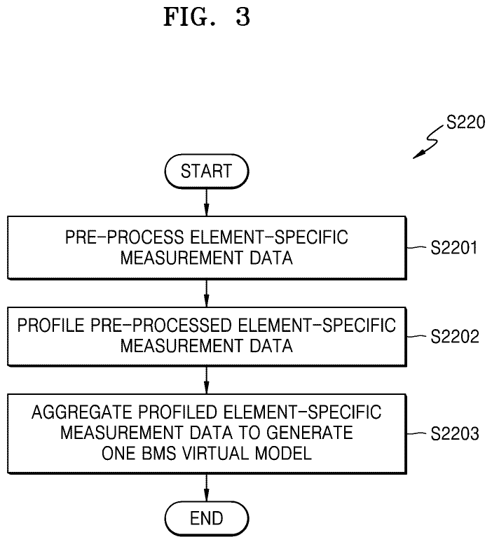

FIG. 3 is a flowchart of a method of generating a BMS virtual model of a BMS according to embodiments of the present disclosure.

Referring to FIG. 3, the virtualizing module 120 may pre-process the element-specific measurement data, in operation S2201.

In some embodiments, the virtualizing module 120 may normalize the element-specific measurement data and generate feature data based on the element-specific measurement data, thereby pre-processing the element-specific measurement data.

The virtualizing module 120 may next profile the pre-processed element-specific measurement data, in operation S2202.

In some embodiments, the virtualizing module 120 may generate an element-specific unique profile based on the pre-processed element-specific measurement data and group elements having similar unique profiles, thereby profiling the pre-processed element-specific measurement data.

The unique profile of the element may result from, for example, analysis of data regarding electrical characteristics, response time and input/output processing capabilities.

The virtualizing module 120 may generate one BMS virtual model by aggregating the profiled element-specific measurement data, in operation S2203.

The BMS virtual model may reflect a structure and a function inside the actual BMS that is a target for collecting the element-specific measurement data.

The virtualizing module 120 may verify whether the generated BMS virtual model matches the actual BMS architecture, by, in some embodiments, using a statistical indicator.

The virtualizing module 120 may generate an emulation file that is a target for emulation in the next step.

Referring back to FIG. 2, the emulating module 130 may perform emulation for each scenario using the BMS virtual model, in operation S230.

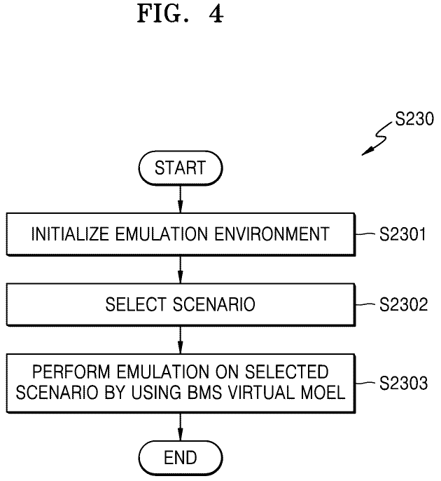

FIG. 4 is a flowchart of a method of performing emulation using a BMS virtual model of a BMS according to embodiments of the present disclosure.

Referring to FIG. 4, the emulating module 130 may initialize an emulation environment, in operation S2301.

The emulating module 130 may initialize the emulation environment, allocate a required resource and load an emulation file provided by the virtualizing module 120, as a step of preparing for emulation.

The emulating module 130 may select a scenario in operation S2302 and perform emulation of the selected scenario using the BMS virtual model in operation S2303.

In one or more embodiments, a scenario may be a set of rules required for an operation of the BMS. The rules of the scenario may include, for example, a surrounding environment of the BMS, an operation of each element of the BMS, a combination of operations of elements, etc.

The emulating module 130 may perform emulation using the BMS virtual model on the selected scenario and may generate emulation result data.

Referring back to FIG. 2, the data analyzing module 140 may analyze the emulation result data to output whether the BMS is defective and a countermeasure therefor, in operation S240.

In some embodiments, the data analyzing module 140 may pre-process the emulation result data, perform machine learning based on the pre-processed emulation result data, determine whether the BMS is defective, based on a result of the machine learning, and generate a countermeasure according to whether the BMS is defective.

Through data pre-processing by the data analyzing module 140, analysis may become accurate and be facilitated.

Through data analysis based on machine learning of the data analyzing module 140, an operating pattern of the BMS may be diagnosed and a predictive failure probability may be predicted using the operating pattern.

If it is determined that there is a defect in the BMS, through data analysis, for example, machine learning, the data analyzing module 140 may identify a cause for the defect.

The data analyzing module 140 may identify one or more causes for a defect from, for example, a scenario where a data analysis result includes a determination that there is a defect and an emulation file, etc.

The data analyzing module 140 may generate an appropriate countermeasure against the defect. The data analyzing module 140 may provide, in some embodiments, a predetermined countermeasure according to a type of the defect.

In some embodiments, the description of conventional electronic configurations, control systems, software, and other functional aspects of the systems may be omitted. Connections of lines or connection members between components shown in the drawings are illustrative of functional connections and/or physical or circuit connections, and in practice, may be expressed as alternative or additional various functional connections, physical connections, or circuit connections.

In describing embodiments and in the claims, the use of the term “the” and similar indicators thereof may correspond to both the singular and the plural. In addition, if the range is described in the embodiments, the range includes the disclosure to which an individual value falling within the range is applied (unless stated otherwise) and is the same as the description of an individual value constituting the range in the detailed description of the present disclosure. If there is no apparent description of the order of operations constituting the method according to embodiments or a contrary description thereof, the operations may be performed in an appropriate order. However, the order of operations may vary.

Exemplary embodiments have been presented herein, and even if certain terms are used, these terms are not used for limited purposes, unless expressly stated, but should be interpreted as general and for explanation. In some embodiments, it may be clear to those of ordinary skill in the art at the time of filing the present application, but characteristics and/or components described in relation to certain embodiments may be used alone unless they are specifically described differently, and may be used with features and/or components described in connection with other embodiments.

One or more embodiments verify performance of a battery management system (BMS) based on measurement data and virtual data for an element included in the BMS.

One or more embodiments also predict performance of a BMS in real time and prepare for a prediction result in a process of manufacturing the BMS.

According to the present disclosure, by measuring and virtualizing individual characteristics of each hardware element of the BMS, a defect of the BMS, which may occur in a manufacturing process, may be sensed and analyzed, in real time.

By sensing and analyzing the defect of the BMS through emulation based on virtualized data, a time may be shortened and a cost may be reduced when compared to sensing and analysis of a defect of an actually manufactured BMS.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An apparatus for verifying performance of a battery management system (BMS), the apparatus comprising:
a data collecting module configured to collect element-specific measurement data of the BMS;
a virtualizing module configured to generate, based on the element-specific measurement data, a BMS virtual model;
an emulating module configured to perform emulation for each of a plurality of scenarios using the BMS virtual model; and
a data analyzing module configured to analyze emulation result data and output whether the BMS is defective, and output a countermeasure.

2. The apparatus as claimed in claim 1, wherein the element-specific measurement data includes at least one of identification data, electrical response characteristic data, power characteristic data, input/output response characteristic data and sensing data.

3. The apparatus as claimed in claim 2, wherein the at least one of the electrical response characteristic data, the power characteristic data, the input/output response characteristic data, and the sensing data indicates an average value of a plurality of measurement data.

4. The apparatus as claimed in claim 1, wherein the virtualizing module is further configured to pre-process the element-specific measurement data, profile the pre-processed element-specific measurement data and aggregate the profiled element-specific measurement data to generate the BMS virtual model.

5. The apparatus as claimed in claim 4, wherein the virtualizing module is further configured to pre-process the element-specific measurement data by performing at least one of normalization of the element-specific measurement data and generation of feature data based on the element-specific measurement data.

6. The apparatus as claimed in claim 4, wherein the virtualizing module is further configured to profile the pre-processed element-specific measurement data by performing at least one of: generation of an element-specific unique profile based on the pre-processed element-specific measurement data; and grouping of elements having similar unique profiles.

7. The apparatus as claimed in claim 6, wherein each of the unique profiles generated include data of an element regarding electrical characteristics, response time and input/output processing capabilities.

8. The apparatus as claimed in claim 1, wherein the emulating module is further configured to initialize an emulation environment, select a scenario of the plurality of scenarios and perform emulation of the selected scenario using the BMS virtual model.

9. The apparatus as claimed in claim 1, wherein the data analyzing module is further configured to:
pre-process the emulation result data;
perform machine learning based on the pre-processed emulation result data;
determine, based on a result of performing the machine learning, whether the BMS is defective; and
generate a countermeasure according to whether the BMS is defective.

10. The apparatus as claimed in claim 9, wherein the data analyzing module is further configured to, if it is determined that there is a defect in the BMS, identify a cause for the defect and generate an appropriate countermeasure against the defect.

11. A method of verifying performance of a battery management system (BMS), the method including:
collecting, by a data collecting module, element-specific measurement data of the BMS;
generating, by a virtualizing module, a BMS virtual model, based on the element-specific measurement data;
performing, by an emulating module, emulation for each of a plurality of scenarios using the BMS virtual module; and
analyzing, by a data analyzing module, emulation result data, and outputting whether the BMS is defective and outputting a countermeasure.

12. The method as claimed in claim 11, wherein the element-specific measurement data includes at least one of identification data, electrical response characteristic data, power characteristic data, input/output response characteristic data, and sensing data.

13. The method as claimed in claim 12, wherein the at least one of the electrical response characteristic data, the power characteristic data, the input/output response characteristic data, and the sensing data indicates an average value of a plurality of measurement data.

14. The method as claimed in claim 11, wherein the generating of the BMS virtual model includes:
pre-processing the element-specific measurement data;
profiling the pre-processed element-specific measurement data; and
aggregating the profiled element-specific measurement data to generate the BMS virtual model.

15. The method as claimed in claim 14, wherein the pre-processing of the element-specific measurement data includes pre-processing the element-specific measurement data by performing at least one of: normalization of the element-specific measurement data; and generation of feature data based on the element-specific measurement data.

16. The method as claimed in claim 14, wherein the profiling of the pre-processed element-specific measurement data includes profiling the pre-processed element-specific measurement data by performing at least one of: generation of an element-specific unique profile based on the pre-processed element-specific measurement data; and grouping of elements having similar unique profiles.

17. The method as claimed in claim 16, wherein the unique profiles include data of an element regarding electrical characteristics, response time and input/output processing capabilities.

18. The method as claimed in claim 11, wherein the performing of emulation for the plurality of scenarios includes:
initializing an emulation environment;
selecting a scenario of the plurality of scenarios; and
performing emulation of the selected scenario using the BMS virtual model.

19. The method as claimed in claim 11, wherein the outputting of whether the BMS is defective and the outputting of the countermeasure include:
pre-processing, by the data analyzing module, the emulation result data;
performing machine learning based on the pre-processed emulation result data;
determining, based on a result of performing the machine learning, whether the BMS is defective; and
generating a countermeasure according to whether the BMS is defective.

20. The method as claimed in claim 19, further including:
identifying, by the data analyzing module, if it is determined that there is a defect in the BMS, a cause for the defect; and
generating, by the data analyzing module, an appropriate countermeasure against the defect.
